(19) United States
(12) Patent Application Publication
(10) Pub. No.: US 2023/0389338 A1
(43) Pub. Date: Nov. 30, 2023

(54) RESISTIVE MEMORY DEVICE AND METHOD OF MANUFACTURING THE SAME

(71) Applicant: SK hynix Inc., Icheon-si Gyeonggi-do (KR)

(72) Inventor: In Ku KANG, Icheon-si Gyeonggi-do (KR)

(73) Assignee: SK hynix Inc., Icheon-si Gyeonggi-do (KR)

(21) Appl. No.: 17/988,267

(22) Filed: Nov. 16, 2022

(30) Foreign Application Priority Data
May 27, 2022 (KR) 10-2022-0065574

(51) Int. Cl. H01L 47/00

(52) U.S. Cl. CPC H01L 27/2436; H01L 45/1675; H01L 45/124

(57) ABSTRACT

The present technology relates to a resistive memory device and a method of manufacturing the same. The resistive memory device includes a stack structure in which a plurality of interlayer insulating layers and a plurality of conductive layers are alternately stacked, a hole passing through the stack structure in a vertical direction, a gate insulating layer, a channel layer, and a variable resistance layer sequentially formed along a sidewall of the hole, and a high dielectric layer formed between the channel layer and the gate insulating layer, the high dielectric layer being adjacent to the plurality of interlayer insulating layers.

### CROSS-REFERENCE TO RELATED APPLICATION

The present application claims priority under 35 U.S.C. § 119(a) to Korean patent application number 10-2022-0065574 filed on May 27, 2022, in the Korean Intellectual Property Office, the entire disclosure of which is incorporated by reference herein.

### BACKGROUND

### 1. Technical Field

The present disclosure relates to a resistive memory device and a method of operating the same, and more particularly, to a resistive memory device capable of storing data according to a resistance change, and a method of manufacturing the same.

### 2. Related Art

A memory device may be divided into a volatile memory device in which stored data is destroyed when power supply is cut off, and a nonvolatile memory device in which stored data is maintained even though power supply is cut off.

The nonvolatile memory device may include a NAND flash memory, a NOR flash memory, a resistive random access memory (ReRAM), a phase-change random access memory (PRAM), a magneto resistive random access memory (MRAM), a ferroelectric random access memory (FRAM), a spin transfer torque random access memory (STT-RAM), and the like.

Among these, the ReRAM may store data according to a resistance change of a variable resistance layer. For example, the ReRAM may include an upper electrode and a lower electrode to which a voltage is applied and may include the variable resistance layer that is disposed between the upper electrode and the lower electrode to store data. The variable resistance layer may be programmed to a high resistance status or a low resistance status according to the voltage that is applied to the upper electrode and the lower electrode. The variable resistance layer may be maintained as the high resistance status or the low resistance status, which is a previous status, until another voltage is applied to the upper electrode or the lower electrode.

### SUMMARY

According to an embodiment of the present disclosure, a resistive memory device includes a stack structure in which a plurality of interlayer insulating layers and a plurality of conductive layers are alternately stacked, a hole passing through the stack structure in a vertical direction, a gate insulating layer, a channel layer, and a variable resistance layer sequentially formed along a sidewall of the hole, and a high dielectric layer formed between the channel layer and the gate insulating layer, the high dielectric layer being adjacent to the plurality of interlayer insulating layers.

According to an embodiment of the present disclosure, a resistive memory device includes a stack structure in which a plurality of interlayer insulating layers and a plurality of conductive layers are alternately stacked, a hole passing through the stack structure in a vertical direction, a channel layer and a variable resistance layer sequentially formed along a sidewall of the hole, a gate insulating layer disposed between the plurality of conductive layers and the channel layer, and a high dielectric layer disposed between the plurality of interlayer insulating layers and the channel layer.

According to an embodiment of the present disclosure, a resistive memory device includes a stack structure in which a plurality of interlayer insulating layers and a plurality of conductive layers are alternately stacked, a hole passing through the stack structure in a vertical direction, a gate insulating layer, a channel layer, and a variable resistance layer sequentially formed along a sidewall of the hole, and a high dielectric layer formed between a sidewall of the plurality of interlayer insulating layers and the gate insulating layer.

According to an embodiment of the present disclosure, a method of manufacturing a resistive memory device includes forming a hole passing through a stack structure in which a plurality of first material layers and a plurality of second material layers are alternately stacked in a vertical direction, forming recess areas by etching sidewalls of the plurality of first material layers, exposed through the hole, to a predetermined depth, forming a gate insulating layer along a sidewall of the hole including the recess areas and forming a high dielectric layer on the gate insulating layer in the recess areas, and forming a channel layer and a variable resistance layer along a sidewall of the gate insulating layer and a sidewall of the high dielectric layer.

According to an embodiment of the present disclosure, a method of manufacturing a resistive memory device includes forming a hole passing through a stack structure in which a plurality of first material layers and a plurality of second material layers are alternately stacked in a vertical direction, forming recess areas by etching sidewalls of the plurality of first material layers, exposed through the hole, to a predetermined depth, forming a first sacrificial layer along a sidewall of the hole including the recess areas and forming a second sacrificial layer on the first sacrificial layer in the recess areas, forming a gate insulating layer by oxidizing a portion of the first sacrificial layer, the portion of the first sacrificial layer that is formed on sidewalls of the plurality of second material layer, removing the remaining first sacrificial layer and second sacrificial layer, and forming a high dielectric layer in recess areas from which the first sacrificial layer and the second sacrificial layer are removed, and forming a channel layer and a variable resistance layer along a sidewall of the gate insulating layer and a sidewall of the high dielectric layer.

According to an embodiment of the present disclosure, a method of manufacturing a resistive memory device includes forming a hole passing through a stack structure in which a plurality of first material layers and a plurality of second material layers are alternately stacked in a vertical direction, forming recess areas by etching sidewalls of the plurality of first material layers, exposed through the hole, to a predetermined depth, forming a high dielectric layer in the recess area, and forming a gate insulating layer, a channel layer, and a variable resistance layer along a sidewall of the plurality of second material layers and a sidewall of the high dielectric layer.

According to an embodiment of the present disclosure, a method of manufacturing a resistive memory device includes forming a hole passing through a stack structure in which a plurality of first material layers and a plurality of second material layers are alternately stacked in a vertical direction, forming recess areas by etching sidewalls of the plurality of first material layers, exposed through the hole, to a predetermined depth, forming a high dielectric layer in the recess areas, forming a gate insulating layer on a sidewall of the plurality of second material layers, and forming a gate insulating layer, a channel layer, and a variable resistance layer along a sidewall of the gate insulating layer and a sidewall of the high dielectric layer.

### BRIEF DESCRIPTION OF THE DRAWINGS

FIG. 1 is a diagram illustrating a resistive memory device according to an embodiment of the present disclosure.

FIG. 2 is a diagram illustrating a status of a resistive memory cell according to an embodiment of the present disclosure.

FIG. 3 is a cross-sectional view illustrating a resistive memory device according to an embodiment of the present disclosure.

FIGS. 4A to 4E are cross-sectional views illustrating a method of manufacturing a resistive memory device according to an embodiment of the present disclosure.

FIG. 5 is a cross-sectional view illustrating a resistive memory device according to another embodiment of the present disclosure.

FIGS. 6A to 6H are cross-sectional views illustrating a method of manufacturing a resistive memory device according to another embodiment of the present disclosure.

FIG. 7 is a cross-sectional view illustrating a resistive memory device according to still another embodiment of the present disclosure.

FIGS. 8A to 8E are cross-sectional views illustrating a method of manufacturing a resistive memory device according to still another embodiment of the present disclosure.

FIG. 9 is a cross-sectional view illustrating a resistive memory device according to still another embodiment of the present disclosure.

FIGS. 10A to 10E are cross-sectional views illustrating a method of manufacturing a resistive memory device according to still another embodiment of the present disclosure.

FIG. 11 is a diagram illustrating a memory card system to which a resistive memory device of the present disclosure is applied.

FIG. 12 is a diagram illustrating a solid state drive (SSD) system to which a resistive memory device of the present disclosure is applied.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and should not be construed as being limited to the embodiments described in the present specification or application.

An embodiment of the present disclosure is to provide a resistive memory device in which channel mastery of a transistor is reduced, and a method of manufacturing the same.

According to the present technology, channel mastery of a transistor may be reduced, and thus, an effective channel length may be reduced.

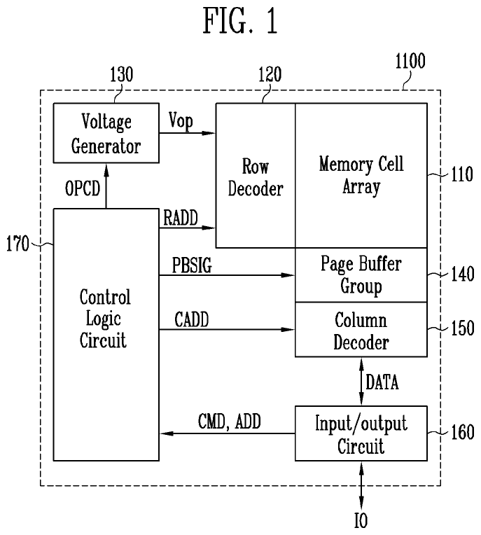

FIG. 1 is a diagram illustrating a resistive memory device according to an embodiment of the present disclosure.

Referring to FIG. 1, the resistive memory device 1100 may include a memory cell array 110 in which data is stored, and a peripheral circuit 120 to 170 capable of performing a program, read, or erase operation.

The memory cell array 110 may include a plurality of memory blocks in which data is stored. Each of the memory blocks may include resistive memory cells (resistive random access memory cells), and the resistive memory cells may be implemented in a three-dimensional structure in which the resistive memory cells are stacked on a substrate in a vertical direction. The resistive memory cells may be configured so that a resistance changes according to a voltage that is applied to an electrode.

The peripheral circuit 120 to 170 may include a row decoder 120, a voltage generator 130, a page buffer group 140, a column decoder 150, and an input/output circuit 160, and a control logic circuit 170.

The row decoder 120 may select one memory block from among the memory blocks that are included in the memory cell array 110 according to a row address RADD and may transmit operation voltages Vop to the selected memory block.

In response to an operation code OPCD, the voltage generator 130 may generate and output the operation voltages Vop that are required for various operations. For example, the voltage generator 130 may generate a set voltage, a reset voltage, a turn-on voltage, a turn-off voltage, a read voltage, an erase voltage, or the like in response to the operation code OPCD and may selectively output the generated voltages. According to the present embodiment, the voltage generator 130 may generate voltages of 0V or higher as voltages to be applied to the word lines and might not include a device that generates a negative voltage lower than 0V.

The page buffer group 140 may be connected to the memory cell array 110 through bit lines. For example, the page buffer group 140 may include page buffers that are connected to each of the bit lines. The page buffers may operate simultaneously in response to page buffer control signals PBSIG and may temporarily store data during a program or read operation. During the read operation or a verify operation, the page buffers may sense a current of the bit lines, which varies according to a threshold voltage of the memory cells. For example, since the current of the bit lines decreases when a resistance of the resistive memory cells increases, and the current of the bit lines increases when the resistance of the resistive memory cells decreases, the page buffers may be configured to sense the current of the bit lines, which varies according to a resistance of selected memory cells.

The column decoder 150 may transmit data DATA between the input/output circuit 160 and the page buffer group 140 according to a column address CADD.

The input/output circuit 160 may be connected to an external device through input/output lines IO. For example, the external device may be a controller capable of transmitting a command CMD, an address ADD, or the data DATA to the resistive memory device 1100. The input/output circuit 160 may input/output the command CMD, the address ADD, and the data DATA through the input/output lines IO. For example, the input/output circuit 160 may transmit the command CMD and the address ADD that are received from the external device through the input/output lines IO to the control logic circuit 170 and may transmit the data DATA that is received from the external device through the input/output lines IO to the column decoder 150. The input/output circuit 160 may output the data DATA that is received from the column decoder 150 to the external device through the input/output lines IO.

The control logic circuit 170 may output the operation code OPCD, the row address RADD, the page buffer control signals PBSIG, and the column address CADD in response to the command CMD and the address ADD. For example, the control logic circuit 170 may include software that performs an algorithm in response to the command CMD and hardware configured to output the address ADD and various control signals.

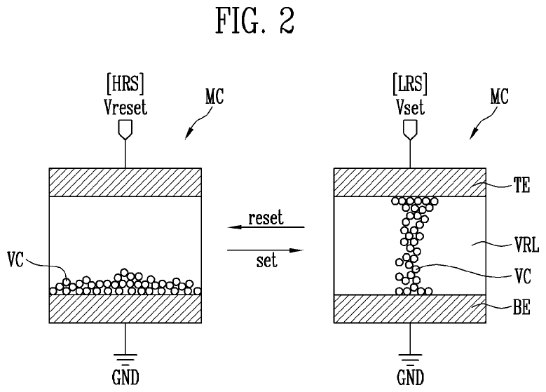

FIG. 2 is a diagram illustrating a status of a resistive memory cell according to an embodiment of the present disclosure.

Referring to FIG. 2, the resistive memory cell MC may include a lower electrode BE, an upper electrode TE, and a variable resistance layer (VRL). The lower electrode BE and the upper electrode TE may be formed of a conductive material, and the variable resistance layer VRL may be formed of a variable resistance material.

The lower electrode BE and the upper electrode TE may be formed of any one or more materials among aluminum (Al), copper (Cu), titanium nitride (TiN), titanium aluminum nitride (TixAlyNz), iridium (Ir), platinum (Pt), silver (Ag), gold (Au), polysilicon, tungsten (W), titanium (Ti), tantalum (Ta), tantalum nitride (TaN), tungsten nitride (WN), nickel (Ni), cobalt (Co), chromium (Cr), antimony (Sb), iron (Fe), molybdenum (Mo), palladium (Pd), tin (Sn), zirconium (Zr), zinc (Zn), iridium oxide (IrO2), and strontium zirconate oxide (StZrO3).

The variable resistance layer VRL may be formed of a bipolar resistive memory material or a unipolar resistive memory material. The bipolar resistive memory material may be in a set or reset status according to different voltages that are applied to the lower electrode BE and the upper electrode TE. A perovskite-based material may be used for the bipolar resistive memory material. The unipolar resistive memory material may be programmed to the set or reset status also by a voltage pulse of the same polarity. As the unipolar resistive memory material, a transition metal oxide, such as nickel oxide (NiOx) or titanium oxide (TiOx), may be used.

In the variable resistance layer VRL, an empty space of atoms exists, which is referred to as a vacancy VC. Since the vacancy VC has a polarity, the vacancy VC may move according to the voltage that is applied to the upper electrode TE and the lower electrode BE. For example, when a reset voltage Vreset is applied to the upper electrode TE and a ground voltage GND is applied to the lower electrode BE, the vacancy VC may move in a direction of the upper electrode TE. Here, the reset voltage Vreset may be a negative voltage that is lower than 0V. When the vacancy VC is concentrated on the upper electrode TE or the lower electrode BE, since a filament is not formed between the upper electrode TE and the lower electrode BE, a resistance of the variable resistance layer VRL may be increased. When the resistance of the variable resistance layer VRL is increased, the resistive memory cell MC be in a high resistance status (HRS), and a current might not flow through the resistive memory cell MC due to a high resistance.

When a set voltage Vset is applied to the upper electrode TE of the resistive memory cell MC in the high resistance status HRS and the ground voltage GND is applied to the lower electrode BE, a portion of the vacancy VC that is concentrated on the upper electrode TE may move to the lower electrode BE, and thus, the filament may be formed between the upper electrode TE and the lower electrode BE. When the filament is formed between the upper electrode TE and the lower electrode BE, since the resistance of the variable resistance layer VRL is decreased, the resistive memory cell MC may be in a low resistance status (LRS). In the resistive memory cell MC, in the low resistance status LRS, a current may flow through the filament between the upper electrode TE and the lower electrode BE.

That is, in the high resistance status HRS, the resistance of the variable resistance layer VRL may increase, and thus, the current may be decreased or might not flow. In the low resistance status LRS, the resistance of the variable resistance layer VRL may be decreased, and thus, the current may be increased. The resistive memory cell MC may be programmed or erased to the set or reset status according to such a change of a resistance status.

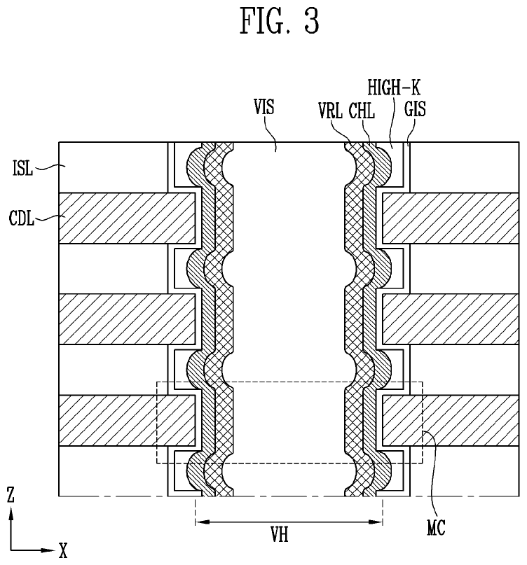

FIG. 3 is a cross-sectional view illustrating a resistive memory device according to an embodiment of the present disclosure.

Referring to FIG. 3, the resistive memory device may include memory blocks including a plurality of resistive memory cells, and FIG. 3 shows a portion of a string included in the memory block.

The string may include a plurality of resistive memory cells MC, and the plurality of resistive memory cells MC may be connected to conductive layers CDL corresponding to word lines. Each of the plurality of resistive memory cells MC may include a transistor including a conductive layer CDL, a gate insulating layer GIS, and a channel layer CHL, and a resistor including the variable resistance layer VRL.

Interlayer insulating layers ISL may be formed between the conductive layers CDL. The conductive layers CDL and the interlayer insulating layers ISL may extend in an X-direction which is a direction that is horizontal to a substrate. For example, the interlayer insulating layers ISL and the conductive layers CDL may be alternately stacked on a lower structure (not shown). The lower structure may include the substrate or at least one of a source line, a source selection line, and peripheral circuits formed on the substrate. The conductive layers CDL may be used as a word line or a selection line. For example, assuming that the interlayer insulating layers ISL and the conductive layers CDL are alternately stacked on the substrate, the conductive layers CDL may include the word line and drain selection lines. The interlayer insulating layers ISL may be formed of an oxide, and the conductive layers CDL may be formed of a metal material, such as tungsten.

A vertical hole VH passing through the interlayer insulating layers ISL and the conductive layers CDL in a Z direction, which is vertical to the substrate, may be formed in the string. The conductive layers CDL may protrude farther into the vertical hole VH compared to the interlayer insulating layers ISL. Accordingly, a rectangular-wave portion may be formed on a sidewall of the vertical hole VH in a vertical direction as shown in FIG. 3. However, the phrase “rectangular-wave portion”, which is disclosed throughout the disclosure, is merely an example, and the present disclosure is not limited thereto. The sidewall of the vertical hole VH may have a different shape, such as a rectangular-wave portion with rounded edges. The sidewall of the vertical hole VH have a concave-convex shape in a vertical direction as shown in FIG. 3. The gate insulating layer GIS, a high dielectric layer HIGH-K, the channel layer CHL, the variable resistance layer VRL, and a vertical insulating layer VIS may be formed inside the vertical hole VH. For example, the gate insulating layer GIS, the channel layer CHL, and the variable resistance layer VRL may be sequentially stacked to be formed on a sidewall of the conductive layers CDL, and the gate insulating layer GIS, the high dielectric layer HIGH-K, the channel layer CHL, and the variable resistance layer VRL may be sequentially stacked to be formed on a sidewall of the interlayer insulating layers ISL. That is, the high dielectric layer HIGH may be formed in a space between protrusions of the conductive layers CDL protruding in a direction of the vertical hole VH compared to the interlayer insulating layers ISL. For example, the high dielectric layer HIGH may have a dielectric constant that is higher than that of the gate insulating layer GIS. For example, when the gate insulating layer GIS is formed of a silicon oxide layer, the high dielectric layer HIGH may be preferably formed of a material having a dielectric constant that is higher than 3.9, which is a dielectric constant of the silicon oxide layer.

In addition, the sidewall of the high dielectric layer HIGH may have a concave shape in relation to the center of the vertical hole VH. Accordingly, the channel layer CHL and the variable resistance layer VRL that are sequentially formed along a sidewall of the high dielectric layer HIGH and a sidewall of the gate insulating layer GIS that is formed on the sidewall of the conductive layers CDL may be formed in a wave-like pattern extending in the vertical direction. For example, the portions of the channel layer CHL and the variable resistance layer VRL that are adjacent to the conductive layers CDL may be formed to be substantially straight in the vertical hole VH, and the portions of the channel layer CHL and the variable resistance layer VRL that are adjacent to the interlayer insulating layers ISL may be formed to be concave in relation to the center of the vertical hole VH.

In the present embodiment, the variable resistance layer VRL may be used as a layer for storing data, and the channel layer CHL may be used for a current to flow in the string.

The gate insulating layer GIS and the vertical insulating layer VIS may be formed of an oxide. The channel layer CHL may be formed of polysilicon. As the variable resistance layer VRL, at least one of a phase variation material, a perovskite-based material, or a transition metal oxide, such as NiOx, HfOx, TaOx, TiOx, or SiHfOx may be used.

According to the above-described embodiment, since the high dielectric layer HIGH is disposed between the conductive layers CDL corresponding to the word line, cross-coupling between the adjacent conductive layers CDL may be increased. This may increase the influence of a bias that is applied to an adjacent word line during an operation of the memory cell corresponding to a selected word line, and thus, channel mastery of a transistor corresponding to the selected word line may be reduced. Accordingly, an effective channel length of the memory cell MC may be decreased.

In addition, the conductive layers CDL corresponding to each of the memory cells may protrude farther into the vertical hole VH compared to the interlayer insulating layers ISL. Portions of the channel layer CHL that are adjacent to the conductive layers CDL may be formed to be substantially straight in the vertical hole VH, and portions of the channel layer CHL that are adjacent to the interlayer insulating layers ISL may be formed to be concave in relation to the center of the vertical hole VH. Therefore, channel mastery of the transistor including the conductive layer CDL, the gate insulating layer GIS, and the channel layer CHL may be decreased, and thus, the effective channel length of the memory cell MC may be decreased.

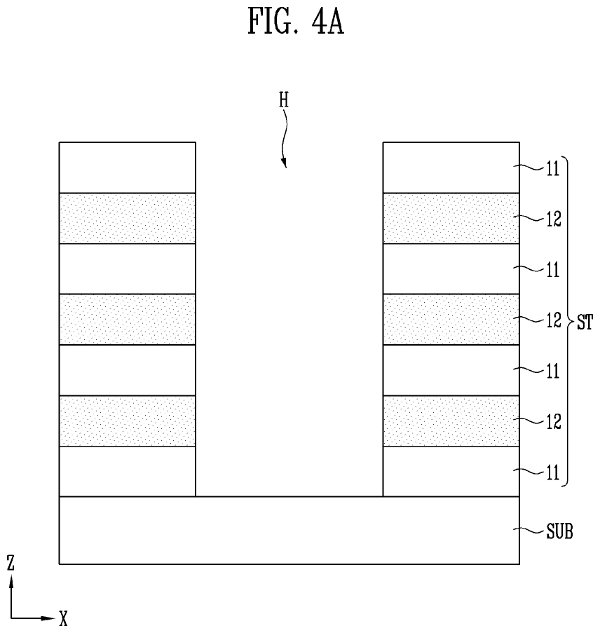

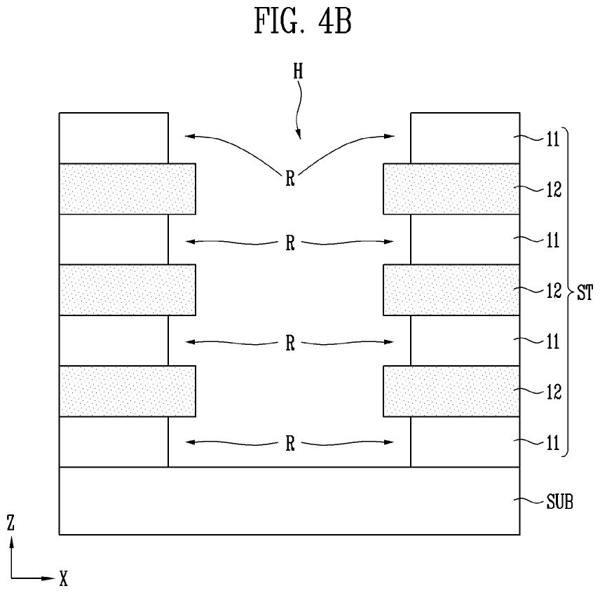

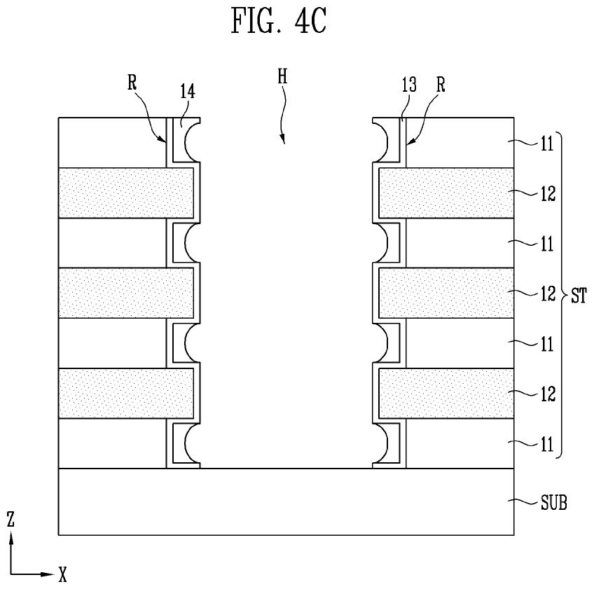

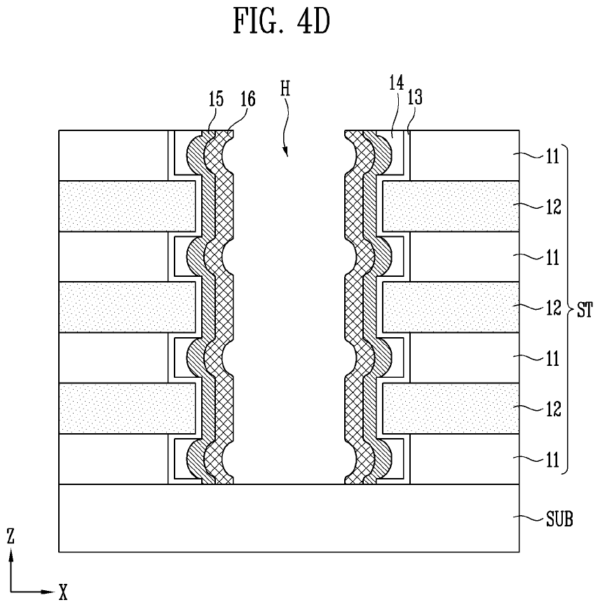

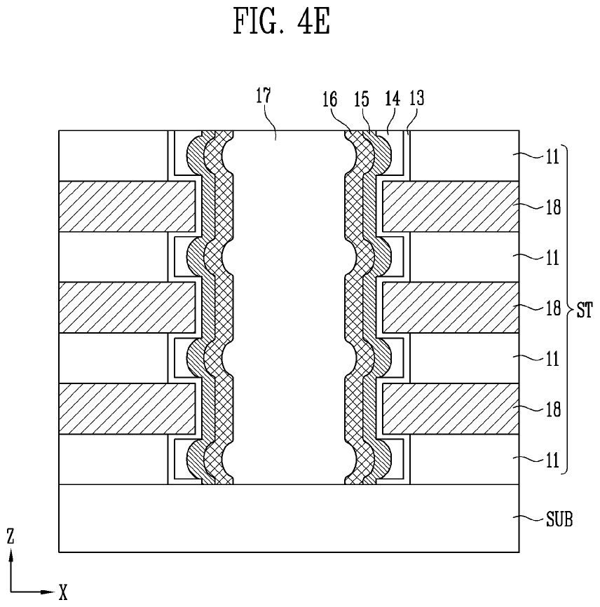

FIGS. 4A to 4E are cross-sectional views illustrating a method of manufacturing a resistive memory device according to an embodiment of the present disclosure.

Referring to FIG. 4A, a stack structure ST may be formed on a substrate SUB. The stack structure ST may include first material layers 11 and second material layers 12 that are alternately stacked. The first and second material layers 11 and 12 may extend in a first direction X, which is horizontal to the substrate SUB. The first and second material layers 11 and 12 may be stacked in a second direction Z, which is vertical to the substrate SUB. The first and second material layers 11 and 12 may be formed through a deposition process such as chemical vapor deposition (CVD).

The first material layers 11 may include a material having a high etch selectivity with respect to the second material layers 12. For example, the first material layers 11 may include an insulating material, such as oxide, and the second material layers 12 may include a sacrificial material, such as nitride. As another example, the first material layers 11 may include an insulating material, such as oxide, and the second material layers 12 may include a conductive material, such as polysilicon, tungsten, molybdenum, or a metal.

Subsequently, a hole H passing through the stack structure ST may be formed. The hole H may have a cylindrical shape extending in the second direction Z.

Referring to FIG. 4B, a sidewall of each of the first material layers 11 exposed through the hole H may be etched to a predetermined depth to form a recess area R. The word “predetermined” as used herein with respect to a parameter, such as a predetermined depth, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm. That is, the sidewall of each of the first material layers 11 may be etched to a predetermined depth so that the second material layers 12 protrude farther than the first material layers 11 in the horizontal direction. The sidewall of each of the first material layers 11 may be etched to have a vertical shape. Accordingly, a sidewall of the hole H may be formed in a structure in which the rectangular-wave portions are sequentially disposed in the second direction Z, which is vertical to the substrate SUB, as shown in FIG. 4B.

Referring to FIG. 4C, a gate insulating layer 13 may be formed along the sidewall of the hole H having the rectangular-wave portion. For example, the gate insulating layer 13 may be formed along the sidewall of each of the first material layers 11 and a protrusion surface of the second material layers 12 that protrude farther than the sidewall of each of the first material layers 11. The gate insulating layer 13 may be formed of an oxide layer.

The gate insulating layer 13 may be formed by forming a sacrificial layer along the sidewall of each of the first material layers 11 and the protrusion surface of the second material layers 12 and replacing the sacrificial layer with an oxide layer by performing a radical oxidation process or a wet oxidation process. For example, the sacrificial layer may be a nitride layer or a polysilicon layer. For example, when the sacrificial layer is formed of the nitride layer, the gate insulating layer 13 may be formed by replacing the nitride layer with the oxide layer through the radical oxidation process. For example, when the sacrificial layer is formed of the polysilicon layer, the polysilicon layer may be replaced with the oxide layer by performing the radical oxidation process or the wet oxidation process to form the gate insulating layer 13.

Thereafter, a high dielectric layer 14 may be formed in a space between protrusions of vertically adjacent second material layers 12. The high dielectric layer 14 may be formed of a material having a dielectric constant that is higher than that of the gate insulating layer 13. For example, after forming the high dielectric layer 14 of a certain thickness on a sidewall of the gate insulating layer 13, an etching process may be performed to cause the high dielectric layer 14 to remain only in a space between the protrusions of vertically adjacent second material layers 12. For example, the high dielectric layer 14 may be disposed only in the space between vertically adjacent conductive layers, among the second material layers 12, as shown in FIG. 4C. That is, a portion of the high dielectric layer 14 may be etched to expose the gate insulating layer 13 that is formed on a sidewall of each of the second material layers 12. A sidewall of the high dielectric layer 14 that is exposed through the hole H may be formed to be concave in relation to the center of the hole H.

Referring to FIG. 4D, the channel layer 15 and the variable resistance layer 16 may be sequentially formed along the exposed surface of the gate insulating layer 13 and the sidewall of the high dielectric layer 14.

The channel layer 15 may be formed of polysilicon. At least one of a phase variation material, a perovskite-based material, or a transition metal oxide, such as NiOx, HfOx, TaOx, TiOx, or SiHfOx, may be used for the variable resistive layer 16.

Since the channel layer 15 is formed along the concave sidewall of the high dielectric layer 14, the channel layer 15 may be formed to have a wave-like pattern in the vertical direction. For example, portions of the channel layer 15 may be formed to be concave in relation to the center of the hole H, and portions of the channel layer 15, between the concavely formed portions, may be formed to be substantially straight based on the contour of the sidewall of each of the second material layers 12. For example, the portions of the channel layer 15 that are adjacent to the first material layers 11 may be defined as a concave areas, and the portions of the channel layer 15 that are adjacent to the second material layers 12 may be defined as substantially straight areas.

Referring to FIG. 4E, a vertical insulating layer 17 may be formed to fill the hole H of FIG. 4D. The vertical insulating layer 17 may be formed of an oxide.

Thereafter, the second material layer 12 of FIG. 4D may be replaced with a third material layer 18. For example, when the second material layers 12 include a sacrificial material and the first material layers 11 include an insulating material, the second material layers 12 may be replaced with conductive layers. The third material layer 18 may include a conductive material, such as polysilicon, tungsten, molybdenum, or a metal.

As another example, when the first material layers 11 include an insulating material and the second material layers 12 include a conductive material, a process of replacing the second material layers 12 with the third material layers 18 may be skipped.

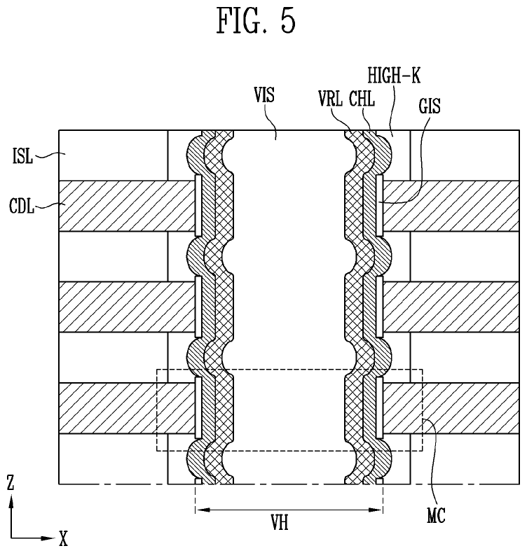

FIG. 5 is a cross-sectional view illustrating a resistive memory device according to another embodiment of the present disclosure.

Referring to FIG. 5, the resistive memory device may include memory blocks including a plurality of resistive memory cells, and FIG. 5 shows a portion of a string included in the memory block.

The string may include a plurality of resistive memory cells MC, and the plurality of resistive memory cells MC may be connected to conductive layers CDL corresponding to word lines. Each of the plurality of resistive memory cells MC may include a transistor including a conductive layer CDL, a gate insulating layer GIS, and a channel layer CHL, and a resistor including a variable resistance layer VRL.

Interlayer insulating layers ISL may be formed between the conductive layers CDL. The conductive layers CDL and the interlayer insulating layers ISL may extend in an X-direction that is horizontal to a substrate. For example, the interlayer insulating layers ISL and the conductive layers CDL may be alternately stacked on a lower structure (not shown). The lower structure may include the substrate or at least one of a source line, a source selection line, and peripheral circuits formed on the substrate. The conductive layers CDL may be used as a word line or a selection line. For example, assuming that the interlayer insulating layers ISL and the conductive layers CDL are alternately stacked on the substrate, the conductive layers CDL may include the word line and drain selection lines. The interlayer insulating layers ISL may be formed of an oxide, and the conductive layers CDL may be formed of a metal material such as tungsten.

A vertical hole VH that passes through the interlayer insulating layers ISL and the conductive layers CDL in a Z direction, which is vertical to the substrate, may be formed in the string. The conductive layers CDL may protrude farther into the vertical hole VH compared to the interlayer insulating layers ISL. Accordingly, a rectangular-wave portion may be formed on a sidewall of the vertical hole VH in a vertical direction as shown in FIG. 5. The gate insulating layer GIS, a high dielectric layer HIGH-K, the channel layer CHL, the variable resistance layer VRL, and a vertical insulating layer VIS may be formed inside the vertical hole VH. For example, the gate insulating layer GIS, the channel layer CHL, and the variable resistance layer VRL may be sequentially stacked to be formed on a sidewall of the conductive layers CDL, and the high dielectric layer HIGH-K, the channel layer CHL, and the variable resistance layer VRL may be sequentially stacked to be formed on a sidewall of the interlayer insulating layers ISL. That is, the high dielectric layer HIGH may be formed in a space between protrusions of vertically adjacent conductive layers CDL that protrude in a direction of the vertical hole VH compared to the interlayer insulating layers ISL, and the gate insulating layer GIS may be formed only on the sidewall of the protruding conductive layers CDL. In addition, the gate insulating layer GIS may further protrude in the Z direction compared to the sidewall of the protruding conductive layers CDL.

For example, the high dielectric layer HIGH may have a dielectric constant that is higher than that of the gate insulating layer GIS. For example, when the gate insulating layer GIS is formed of a silicon oxide layer, the high dielectric layer HIGH may be preferably formed of a material having a dielectric constant that is higher than 3.9, which is the dielectric constant of the silicon oxide layer.

In addition, the sidewall of the high dielectric layer HIGH may have a concave shape in relation to the center of the vertical hole VH. Accordingly, the channel layer CHL and the variable resistance layer VRL that are sequentially formed along a sidewall of the high dielectric layer HIGH and a sidewall of the gate insulating layer GIS that is formed on the sidewall of the conductive layers CDL may be formed in a wave-like pattern extending in the vertical direction. For example, the portions of the channel layer CHL and the variable resistance layer VRL that are adjacent to the conductive layers CDL may be formed to be substantially straight in the vertical hole VH, and the portions of the channel layer CHL and the variable resistance layer VRL that are adjacent to the interlayer insulating layers ISL may be formed to be concave in relation to the center of the vertical hole VH.

In the present embodiment, the variable resistance layer VRL may be used as a layer for storing data, and the channel layer CHL may be used for a current to flow in the string.

The gate insulating layer GIS and the vertical insulating layer VIS may be formed of an oxide. The channel layer CHL may be formed of polysilicon. As the variable resistance layer VRL, at least one of a phase variation material, a perovskite-based material, or a transition metal oxide, such as NiOx, HfOx, TaOx, TiOx, or SiHfOx may be used.

According to the above-described embodiment, since the high dielectric layer HIGH is disposed between the conductive layers CDL corresponding to the word line, cross-coupling between the adjacent conductive layers CDL may be increased. This may increase the influence of a bias that is applied to an adjacent word line during an operation of the memory cell corresponding to a selected word line, and thus, channel mastery of a transistor corresponding to the selected word line may be reduced. Accordingly, an effective channel length of the memory cell MC may be decreased.

In addition, the conductive layers CDL corresponding to each of the memory cells may protrude farther into the vertical hole VH compared to the interlayer insulating layers ISL. Portions of the channel layer CHL that are adjacent to the conductive layers CDL may be formed to be substantially straight in the vertical hole VH, and portions of the channel layer CHL that are adjacent to the interlayer insulating layers ISL may be formed to be concave in relation to the center of the vertical hole VH. Therefore, channel mastery of the transistor including the conductive layer CDL, the gate insulating layer GIS, and the channel layer CHL may be decreased, and thus, the effective channel length of the memory cell MC may be decreased.

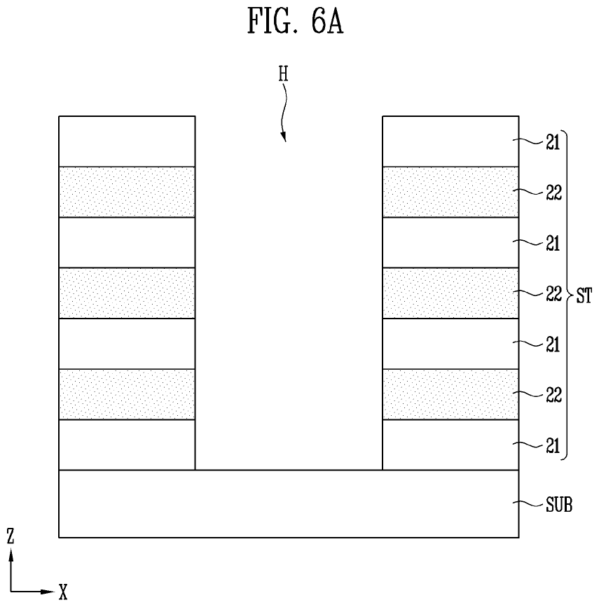

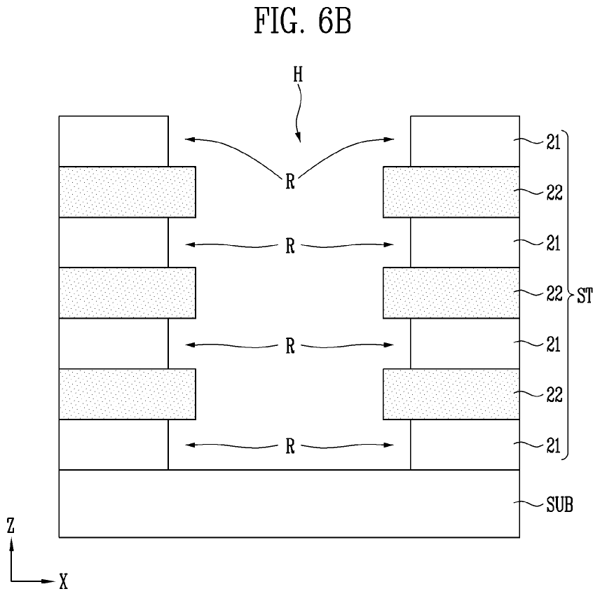

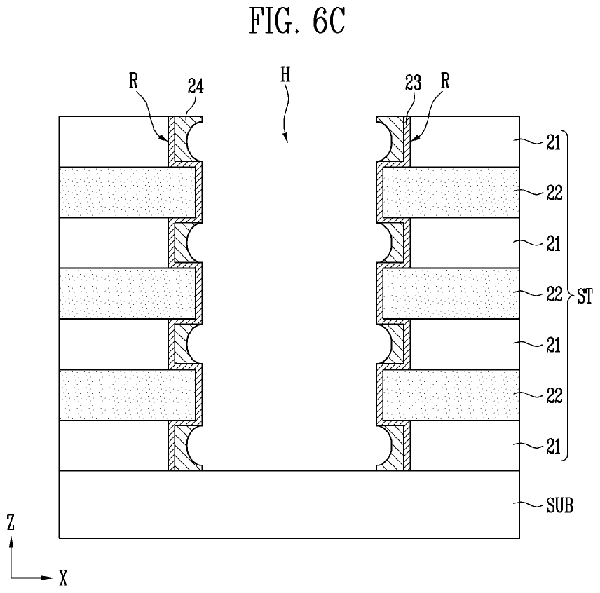

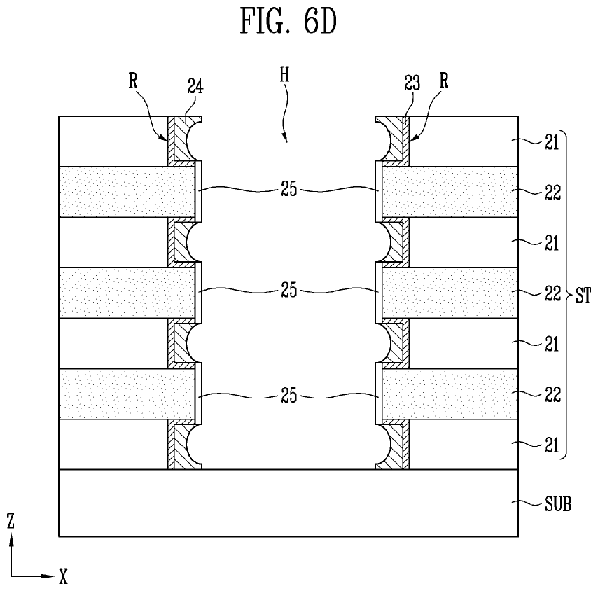

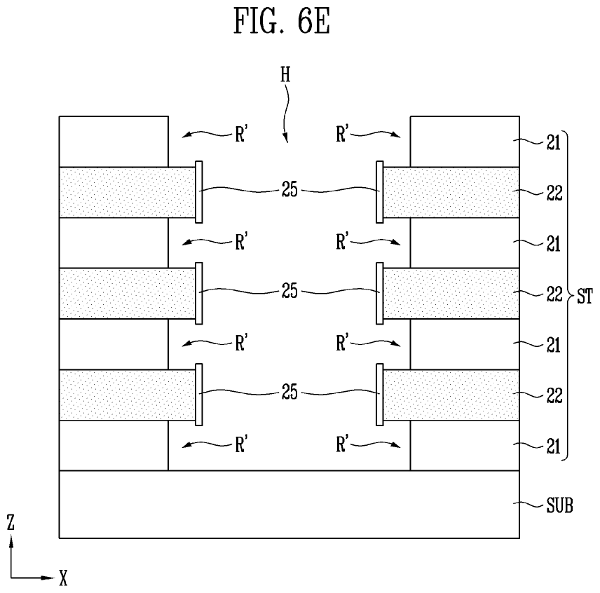

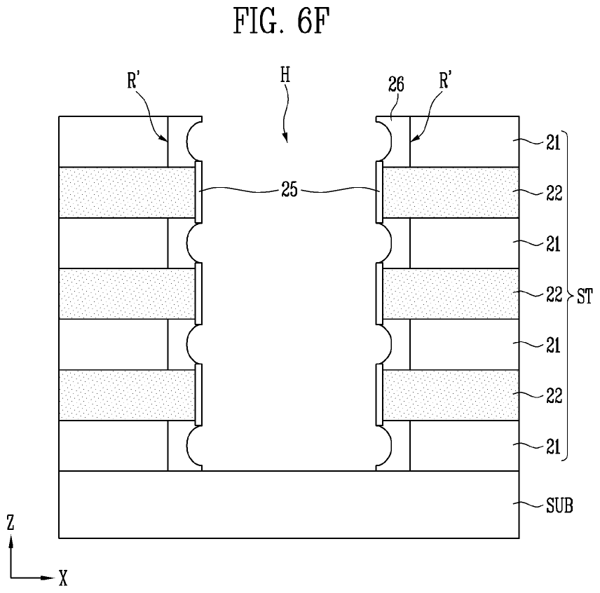

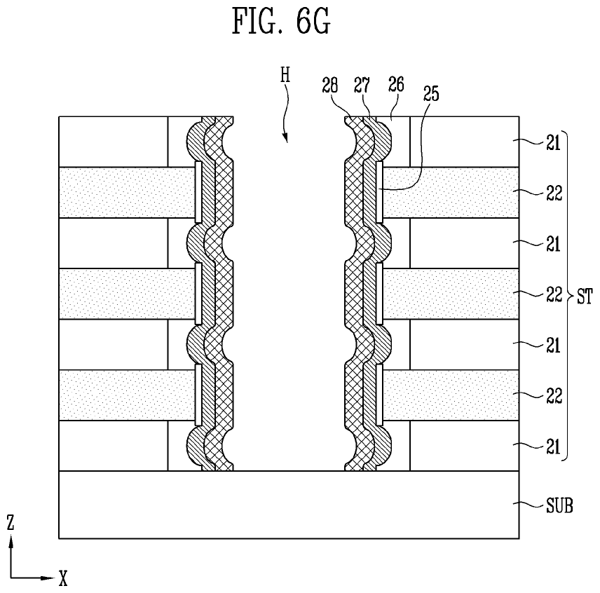

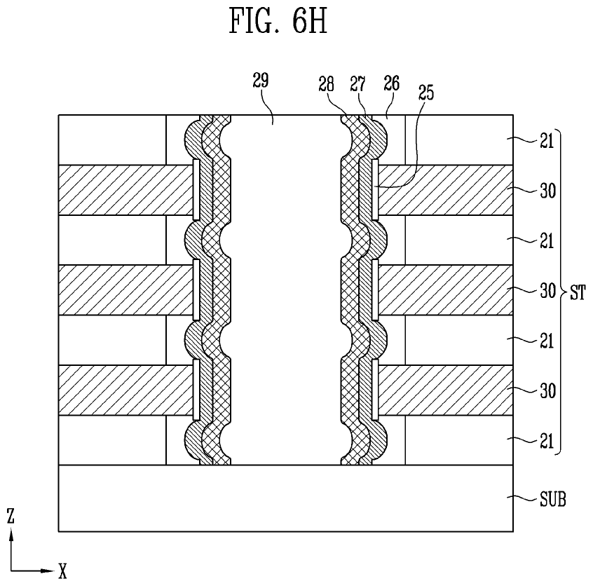

FIGS. 6A to 6H are cross-sectional views illustrating a method of manufacturing a resistive memory device according to another embodiment of the present disclosure.

Referring to FIG. 6A, a stack structure ST may be formed on a substrate SUB. The stack structure ST may include first material layers 21 and second material layers 22 that are alternately stacked. The first and second material layers 21 and 22 may extend in a first direction X, which is horizontal to the substrate SUB. The first and second material layers 21 and 22 may be stacked in a second direction Z, which is vertical to the substrate SUB. The first and second material layers 21 and 22 may be formed through a deposition process, such as chemical vapor deposition (CVD).

The first material layers 21 may include a material having a high etch selectivity with respect to the second material layers 22. For example, the first material layers 21 may include an insulating material such as oxide, and the second material layers 22 may include a sacrificial material such as nitride. As another example, the first material layers 21 may include an insulating material, such as oxide, and the second material layers 22 may include a conductive material, such as polysilicon, tungsten, molybdenum, or a metal.

Subsequently, a hole H that passes through the stack structure ST may be formed. The hole H may have a cylindrical shape extending in the second direction Z.

Referring to FIG. 6B, sidewalls of the first material layers 21 that are exposed through the hole H may be etched to a predetermined depth to form a recess area R. That is, the sidewall of each of the first material layers 21 may be etched to a predetermined depth so that the second material layers 22 protrude farther into the hole H compared to the first material layers 21 in the horizontal direction. The sidewall of each of the first material layers 21 may be etched to have a vertical shape. Accordingly, the sidewall of the hole H may be formed in a structure in which the rectangular-wave portions are sequentially disposed in the second direction Z, which is vertical to the substrate SUB, as shown in FIG. 6B.

Referring to FIG. 6C, a first sacrificial layer 23 may be formed along the sidewall of the hole H having the rectangular-wave portion. For example, the first sacrificial layer 23 may be a polysilicon layer. For example, the first sacrificial layer 23 may be formed along the sidewall of each of the first material layers 21 and a protrusion surface of each of the second material layers 22 that protrude farther into the hole H compared to the sidewall of each of the first material layers 21.

Thereafter, a second sacrificial layer 24 is formed in a space between protrusions of vertically adjacent second material layers 22. For example, the second sacrificial layer 24 may be a nitride layer. For example, the second sacrificial layer 24 of a predetermined thickness may be formed on a sidewall of the first sacrificial layer 23, and then an etching process may be performed to cause the second sacrificial layer 24 to remain only in the space between the protrusions of the second material layers 22. That is, a portion of the second sacrificial layer 24 may be etched to expose the first sacrificial layer 23 that is formed on the sidewall of each of the second material layers 22.

Referring to FIG. 6D, the exposed first sacrificial layer 23 may be oxidized to form a gate insulating layer 25. For example, the gate insulating layer 25 may be formed by oxidizing the first sacrificial layer that is formed on the sidewall of each of the second material layers 22 in a wet oxidation method.

Referring to FIG. 6E, the second sacrificial layer 24 of FIG. 6D and the first sacrificial layer 23 of FIG. 6D that are formed in the space between the protrusions of vertically adjacent second material layers 22 may be removed. Accordingly, the first sacrificial layer and the second sacrificial layer may be removed, and thus, a recess R′ may be formed between the protrusions of vertically adjacent second material layers 22.

Referring to FIG. 6F, a high dielectric layer 26 may be formed in the recess R′ between the protrusions of vertically adjacent second material layers 22.

The high dielectric layer 26 may be preferably formed of a material having a dielectric constant that is higher than that of the gate insulating layer 25. For example, the high dielectric layer 26 may remain in the recess R′ between the protrusions of vertically adjacent second material layers 22 by forming the high dielectric layer 26 so that the recess R′ between the protrusions of vertically adjacent second material layers 22 is filled and then removing the high dielectric layer 26 that remains in an area other than the recess R′ between the protrusions of vertically adjacent second material layers 22 by performing an etching process. A sidewall of the high dielectric layer 26, exposed through the hole H by the etching process, may be concavely formed.

Referring to FIG. 6G, the channel layer 27 and the variable resistance layer 28 may be sequentially formed along the exposed surface of the gate insulating layer 25 and the sidewall of the high dielectric layer 26.

The channel layer 27 may be formed of polysilicon. At least one of a phase variation material, a perovskite-based material, or a transition metal oxide, such as NiOx, HfOx, TaOx, TiOx, or SiHfOx, may be used for the variable resistive layer 28.

Since the channel layer 27 is formed along the concave sidewall of the high dielectric layer 26, the channel layer 27 may be formed to have a wave-like pattern in the vertical direction. For example, portions of the channel layer 27 may be formed to be concave in relation to the center of the hole H, and portions between the concave portions may be formed to be substantially straight based on the contour of the sidewall of each of the second material layers 22. For example, an area of the channel layer 27 adjacent to the first material layer 21 may be defined as a concave area, and an area adjacent to the second material layer 22 may be defined as a substantially straight area.

Referring to FIG. 6H, a vertical insulating layer 29 may be formed to fill the hole H of FIG. 6G. The vertical insulating layer 29 may be formed of an oxide.

Thereafter, the second material layer 22 of FIG. 6G may be replaced with a third material layer 30. For example, when the second material layers 22 include a sacrificial material and the first material layers 21 include an insulating material, the second material layers 22 may be replaced with conductive layers. The third material layer 30 may include a conductive material, such as polysilicon, tungsten, molybdenum, or a metal.

As another example, when the first material layers 21 include an insulating material and the second material layers 22 include a conductive material, a process of replacing the second material layers 22 with the third material layers 30 may be skipped.

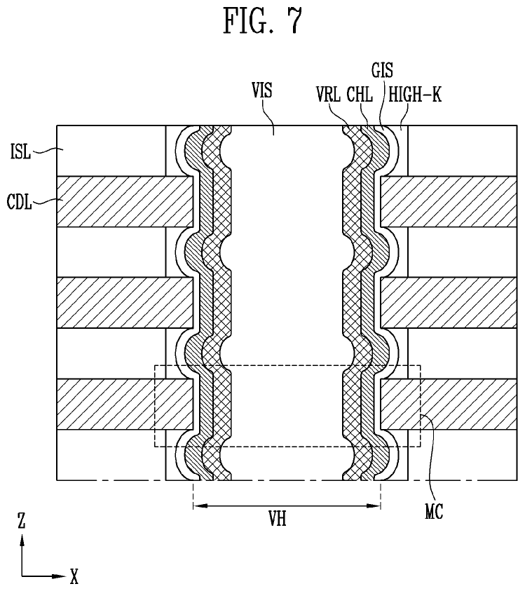

FIG. 7 is a cross-sectional view illustrating a resistive memory device according to still another embodiment of the present disclosure.

Referring to FIG. 7, the resistive memory device may include memory blocks including a plurality of resistive memory cells, and FIG. 7 shows a portion of a string that is included in the memory block.

The string may include a plurality of resistive memory cells MC, and the plurality of resistive memory cells MC may be connected to conductive layers CDL corresponding to word lines. Each of the plurality of resistive memory cells MC may include a transistor including a conductive layer CDL, a gate insulating layer GIS, and a channel layer CHL, and a resistor including the variable resistance layer VRL.

Interlayer insulating layers ISL may be formed between the conductive layers CDL. The conductive layers CDL and the interlayer insulating layers ISL may extend in an X-direction, which is horizontal to a substrate. For example, the interlayer insulating layers ISL and the conductive layers CDL may be alternately stacked on a lower structure (not shown). The lower structure may include the substrate or at least one of a source line, a source selection line, and peripheral circuits formed on the substrate. The conductive layers CDL may be used as a word line or a selection line. For example, assuming that the interlayer insulating layers ISL and the conductive layers CDL are alternately stacked on the substrate, the conductive layers CDL may include the word line and drain selection lines. The interlayer insulating layers ISL may be formed of an oxide, and the conductive layers CDL may be formed of a metal material, such as tungsten.

A vertical hole VH that passes through the interlayer insulating layers ISL and the conductive layers CDL in a Z direction, which is vertical to the substrate, may be formed in the string. The conductive layers CDL may further protrude in a direction that is adjacent to the vertical hole VH compared to the interlayer insulating layers ISL. Accordingly, a rectangular-wave portion may be formed on a sidewall of the vertical hole VH in a vertical direction. A high dielectric layer HIGH-K, the gate insulating layer GIS, the channel layer CHL, the variable resistance layer VRL, and a vertical insulating layer VIS may be formed inside the vertical hole VH. For example, the gate insulating layer GIS, the channel layer CHL, and the variable resistance layer VRL may be sequentially stacked to be formed on a sidewall of the conductive layers CDL, and the high dielectric layer HIGH-K, the gate insulating layer GIS, the channel layer CHL, and the variable resistance layer VRL may be sequentially stacked to be formed on a sidewall of the interlayer insulating layers ISL. That is, the high dielectric layer HIGH may be formed in a space between protrusions of vertically adjacent conductive layers CDL that protrude farther into the vertical hole VH compared to the interlayer insulating layers ISL, and the gate insulating layer GIS may be formed along a sidewall of the high dielectric layer HIGH and the sidewall of the conductive layers CDL. For example, the high dielectric layer HIGH may have a dielectric constant that is higher than that of the gate insulating layer GIS. For example, when the gate insulating layer GIS is formed of a silicon oxide layer, the high dielectric layer HIGH may be preferably formed of a material having a dielectric constant that is higher than 3.9, which is a dielectric constant of the silicon oxide layer.

In addition, the sidewall of the high dielectric layer HIGH may have a concave shape in relation to the center of the vertical hole VH. Accordingly, the gate insulating layer GIS, the channel layer CHL, and the variable resistance layer VRL that are sequentially formed along the sidewall of the conductive layers CDL and the sidewall of the high dielectric layer HIGH may be formed in a wave-like pattern extending in the vertical direction. For example, the portions of the channel layer CHL and the variable resistance layer VRL that are adjacent to the conductive layers CDL may be formed to be substantially straight in the vertical hole VH, and the portions of the channel layer CHL and the variable resistance layer VRL that are adjacent to the interlayer insulating layers ISL may be formed to be concave in relation to the center of the vertical hole VH.

In the present embodiment, the variable resistance layer VRL may be used as a layer for storing data, and the channel layer CHL may be used for a current to flow in the string.

The gate insulating layer GIS and the vertical insulating layer VIS may be formed of an oxide. The channel layer CHL may be formed of polysilicon. As the variable resistance layer VRL, at least one of a phase variation material, a perovskite-based material, or a transition metal oxide, such as NiOx, HfOx, TaOx, TiOx, or SiHfOx, may be used.

According to the above-described embodiment, since the high dielectric layer HIGH is disposed between the conductive layers CDL corresponding to the word line, cross-coupling between the adjacent conductive layers CDL may be increased. This may increase the influence of a bias that is applied to an adjacent word line during an operation of the memory cell corresponding to a selected word line, and thus, channel mastery of a transistor corresponding to the selected word line may be reduced. Accordingly, an effective channel length of the memory cell MC may be decreased.

In addition, the conductive layers CDL corresponding to each of the memory cells may protrude farther into the vertical hole VH compared to the interlayer insulating layers ISL. Portions of the channel layer CHL that are adjacent to the conductive layers CDL may be formed to be substantially straight in the vertical hole VH, and portions of the channel layer CHL that are adjacent to the interlayer insulating layers ISL may be formed to be concave in relation to the center of the vertical hole VH. Therefore, channel mastery of the transistor including the conductive layer CDL, the gate insulating layer GIS, and the channel layer CHL may be decreased, and thus, the effective channel length of the memory cell MC may be decreased.

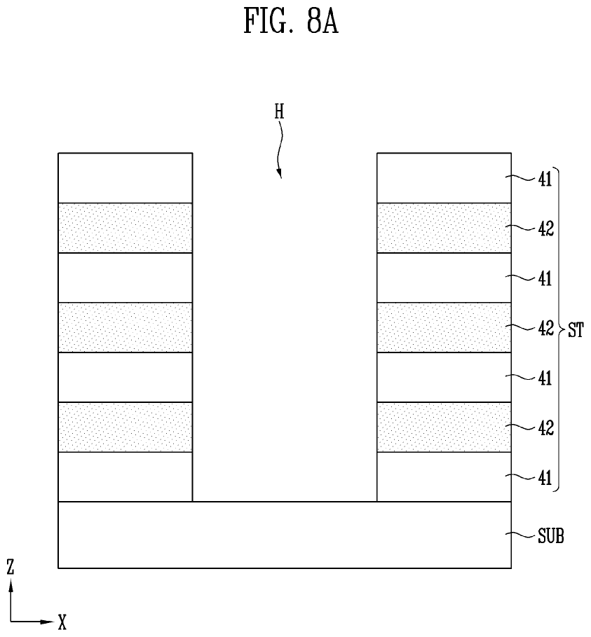

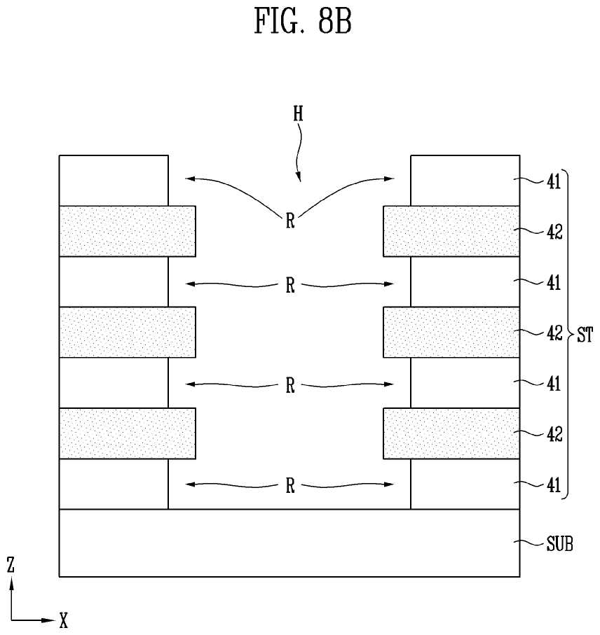

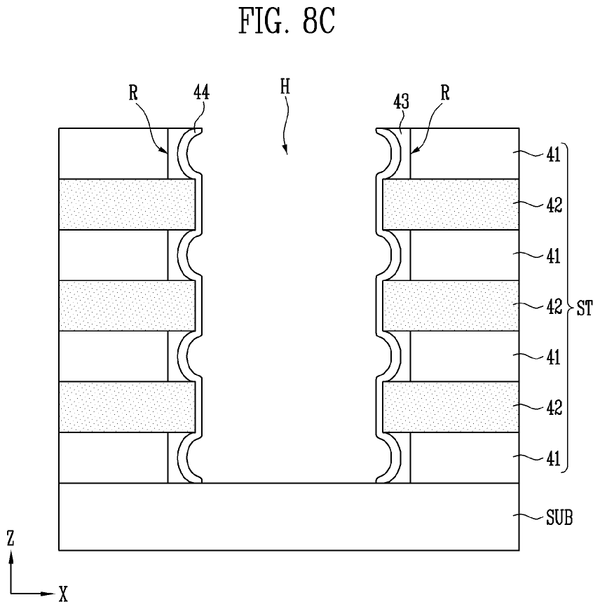

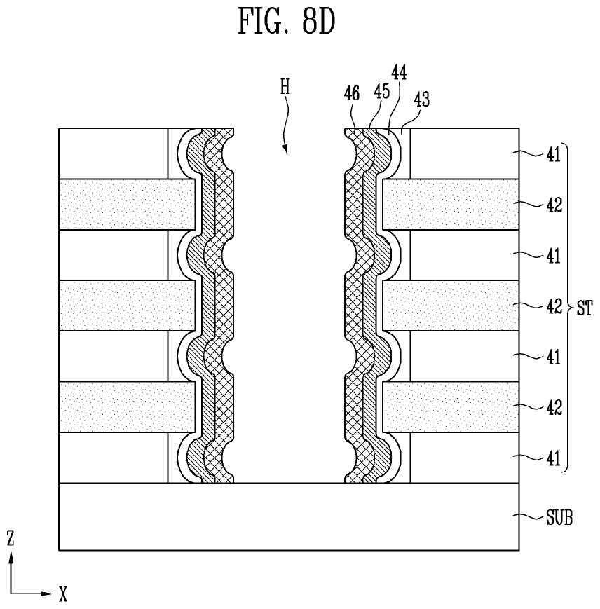

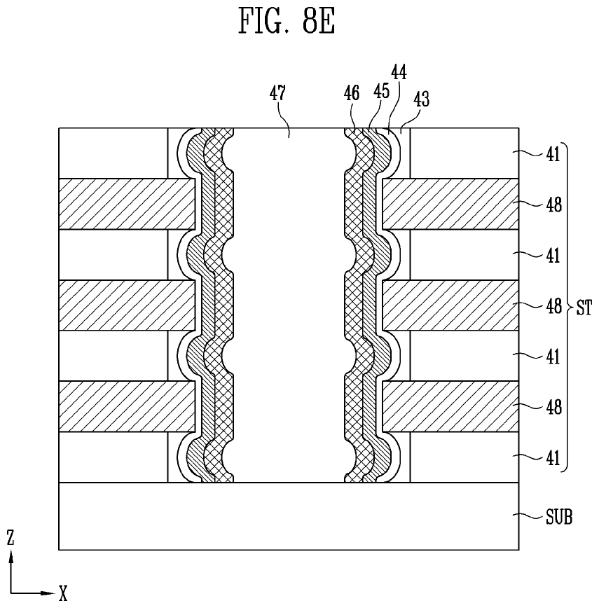

FIGS. 8A to 8E are cross-sectional views illustrating a method of manufacturing a resistive memory device according to still another embodiment of the present disclosure.

Referring to FIG. 8A, a stack structure ST may be formed on a substrate SUB. The stack structure ST may include first material layers 41 and second material layers 42 that are alternately stacked. The first and second material layers 41 and 42 may extend in a first direction X, which is horizontal to the substrate SUB. The first and second material layers 41 and 42 may be stacked in a second direction Z, which is vertical to the substrate SUB. The first and second material layers 41 and 42 may be formed through a deposition process, such as chemical vapor deposition (CVD).

The first material layers 41 may include a material having a high etch selectivity with respect to the second material layers 42. For example, the first material layers 41 may include an insulating material, such as oxide, and the second material layers 42 may include a sacrificial material, such as nitride. As another example, the first material layers 41 may include an insulating material, such as oxide, and the second material layers 42 may include a conductive material, such as polysilicon, tungsten, molybdenum, or a metal.

Subsequently, a hole H passing through the stack structure ST may be formed. The hole H may have a cylindrical shape extending in the second direction Z.

Referring to FIG. 8B, a sidewall of each of the first material layers 41, exposed through the hole H, may be etched to a predetermined depth to form a recess area R. That is, the sidewall of each of the first material layers 41 may be etched to a predetermined depth so that the second material layers 42 protrude farther into the hole H compared to the first material layers 41 in the horizontal direction. The sidewall of each of the first material layers 41 may be etched to have a vertical shape. Accordingly, a sidewall of the hole H may be formed in a structure in which the rectangular-wave portions are sequentially disposed in the second direction Z, which is vertical to the substrate SUB, as shown in FIG. 8B.

Referring to FIG. 8C, a high dielectric layer 43 may be formed in a recess area R, which is a space between the vertically adjacent second material layers 42 that protrude farther into the hole H compared to the first material layers 41. For example, the high dielectric layer 43 may be formed along the sidewall of the hole H, and then an etching process may be performed to cause the high dielectric layer 43 to remain only in the recess area R, which is a space between protrusions of vertically adjacent second material layers 42. A sidewall of the high dielectric layer 43 that is exposed through the etching process may be concavely formed.

Thereafter, a gate insulating layer 44 may be formed along the exposed sidewall of each of the second material layers 42 and the sidewall of the high dielectric layer 43. Accordingly, the gate insulating layer 44 may have a wave-like pattern extending in the vertical direction.

The gate insulating layer 44 may be formed of an oxide layer. The high dielectric layer 43 may be formed of a material having a dielectric constant that is higher than that of the gate insulating layer 44.

The gate insulating layer 44 may be formed by forming a sacrificial layer along the sidewall of each of the second material layers 42 and the sidewall of the high dielectric layer 43 and replacing the sacrificial layer with an oxide layer by performing a radical oxidation process or a wet oxidation process. For example, the sacrificial layer may be a nitride layer or a polysilicon layer. For example, when the sacrificial layer is formed of the nitride layer, the gate insulating layer 44 may be formed by replacing the nitride layer with the oxide layer through the radical oxidation process. For example, when the sacrificial layer is formed of the polysilicon layer, the polysilicon layer may be replaced with the oxide layer by performing the radical oxidation process or the wet oxidation process to form the gate insulating layer 44.

Referring to FIG. 8D, the channel layer 45 and the variable resistance layer 46 may be sequentially formed along a sidewall surface of the exposed gate insulating layer 44.

The channel layer 45 may be formed of polysilicon. At least one of a phase variation material, a perovskite-based material, or a transition metal oxide, such as NiOx, HfOx, TaOx, TiOx, or SiHfOx, may be used for the variable resistive layer 46.

Since the channel layer 45 is formed along the sidewall surface of the gate insulating layer 44, the channel layer 45 may be formed to have a wave-like pattern in the vertical direction. For example, portions of the channel layer 45 may be formed to be concave in relation to a center of the hole H, and portions between the concave portions may be formed to be substantially straight based on the contour of the sidewall of each of the second material layers 42. For example, an area of the channel layer 45 adjacent to the first material layer 41 may be defined as a concave area, and an area adjacent to the second material layer 42 may be defined as a substantially straight area.

Referring to FIG. 8E, a vertical insulating layer 47 may be formed to fill the hole H of FIG. 8D. The vertical insulating layer 47 may be formed of an oxide.

Thereafter, the second material layer 42 of FIG. 8D is replaced with a third material layer 48. For example, when the second material layers 42 include a sacrificial material and the first material layers 41 include an insulating material, the second material layers 42 are replaced with conductive layers. The third material layer 48 may include a conductive material, such as polysilicon, tungsten, molybdenum, or a metal.

As another example, when the first material layers 41 include an insulating material and the second material layers 42 include a conductive material, a process of replacing the second material layers 42 with the third material layers 48 may be skipped.

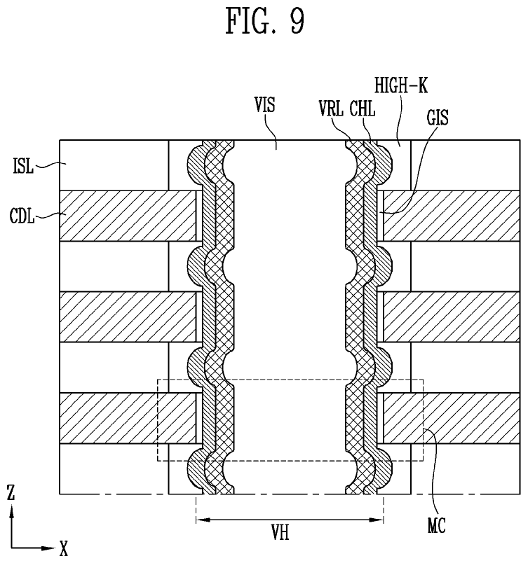

FIG. 9 is a cross-sectional view illustrating a resistive memory device according to still another embodiment of the present disclosure.

Referring to FIG. 9, the resistive memory device may include memory blocks including a plurality of resistive memory cells, and FIG. 9 shows a portion of a string included in the memory block.

The string may include a plurality of resistive memory cells MC, and the plurality of resistive memory cells MC may be connected to conductive layers CDL corresponding to word lines. Each of the plurality of resistive memory cells MC may include a transistor including a conductive layer CDL, a gate insulating layer GIS, and a channel layer CHL, and a resistor including the variable resistance layer VRL.

Interlayer insulating layers ISL may be formed between the conductive layers CDL. The conductive layers CDL and the interlayer insulating layers ISL may extend in an X-direction, which is horizontal to a substrate. For example, the interlayer insulating layers ISL and the conductive layers CDL may be alternately stacked on a lower structure (not shown). The lower structure may include the substrate or at least one of a source line, a source selection line, and peripheral circuits formed on the substrate. The conductive layers CDL may be used as a word line or a selection line. For example, assuming that the interlayer insulating layers ISL and the conductive layers CDL are alternately stacked on the substrate, the conductive layers CDL may include the word line and drain selection lines. The interlayer insulating layers ISL may be formed of an oxide, and the conductive layers CDL may be formed of a metal material, such as tungsten.

A vertical hole VH that passes through the interlayer insulating layers ISL and the conductive layers CDL in a Z direction, which is vertical to the substrate may be formed in the string. The conductive layers CDL may protrude farther into the vertical hole VH compared to the interlayer insulating layers ISL. Accordingly, a rectangular-wave portion may be formed on a sidewall of the vertical hole VH in a vertical direction. The gate insulating layer GIS, a high dielectric layer HIGH-K, the channel layer CHL, the variable resistance layer VRL, and a vertical insulating layer VIS may be formed inside the vertical hole VH. For example, the gate insulating layer GIS, the channel layer CHL, and the variable resistance layer VRL may be sequentially stacked to be formed on a sidewall of the conductive layers CDL, and the high dielectric layer HIGH-K, the channel layer CHL, and the variable resistance layer VRL may be sequentially stacked to be formed on a sidewall of the interlayer insulating layers ISL. That is, the high dielectric layer HIGH may be formed in a space between protrusions of vertically adjacent conductive layers CDL that protrude farther into the vertical hole VH compared to the interlayer insulating layers ISL, and the gate insulating layer GIS may be formed only on the sidewall of the protruding conductive layers CDL. For example, the high dielectric layer HIGH may have a dielectric constant that is higher than that of the gate insulating layer GIS. For example, when the gate insulating layer GIS is formed of a silicon oxide layer, the high dielectric layer HIGH may be preferably formed of a material having a dielectric constant that is higher than 3.9, which is a dielectric constant of the silicon oxide layer.

In addition, the sidewall of the high dielectric layer HIGH may have a concave shape in relation to the center of the vertical hole VH. Accordingly, the channel layer CHL and the variable resistance layer VRL that are sequentially formed along the sidewall of the high dielectric layer HIGH and the sidewall of the gate insulating layer GIS that is formed on the sidewall of the conductive layers CDL may be formed in a wave-like pattern extending in the vertical direction. For example, the portions of the channel layer CHL and the variable resistance layer VRL that are adjacent to the conductive layers CDL may be formed to be substantially straight in the vertical hole VH, and the portions of the channel layer CHL and the variable resistance layer VRL that are adjacent to the interlayer insulating layers ISL may be formed to be concave in relation to the center of the vertical hole VH.

In the present embodiment, the variable resistance layer VRL may be used as a layer for storing data, and the channel layer CHL may be used for a current to flow in the string.

The gate insulating layer GIS and the vertical insulating layer VIS may be formed of an oxide. The channel layer CHL may be formed of polysilicon. As the variable resistance layer VRL, at least one of a phase variation material, a perovskite-based material, or a transition metal oxide, such as NiOx, HfOx, TaOx, TiOx, or SiHfOx, may be used.

According to the above-described embodiment, since the high dielectric layer HIGH is disposed between the conductive layers CDL corresponding to the word line, cross-coupling between the adjacent conductive layers CDL may be increased. This may increase the influence of a bias that is applied to an adjacent word line during an operation of the memory cell corresponding to a selected word line, and thus, channel mastery of a transistor corresponding to the selected word line may be reduced. Accordingly, an effective channel length of the memory cell MC may be decreased.

In addition, the conductive layers CDL corresponding to each of the memory cells may protrude farther into the vertical hole VH compared to the interlayer insulating layers ISL. Portions of the channel layer CHL may be formed to be substantially straight in the vertical hole VH, and portions of the channel layer CHL that are adjacent to the interlayer insulating layers ISL may be formed to be concave in relation to the center of the vertical hole VH. Therefore, channel mastery of the transistor including the conductive layer CDL, the gate insulating layer GIS, and the channel layer CHL may be decreased, and thus, the effective channel length of the memory cell MC may be decreased.

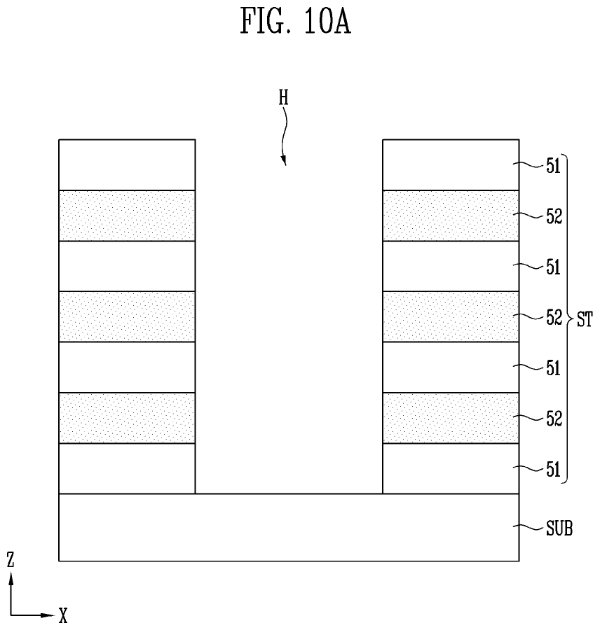

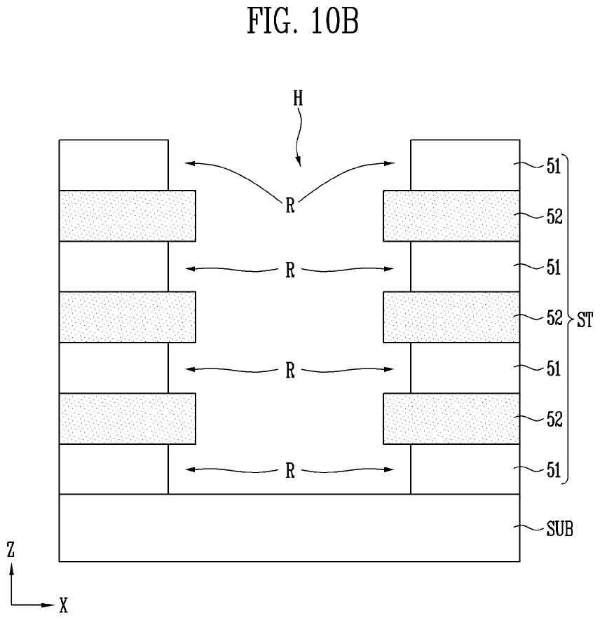

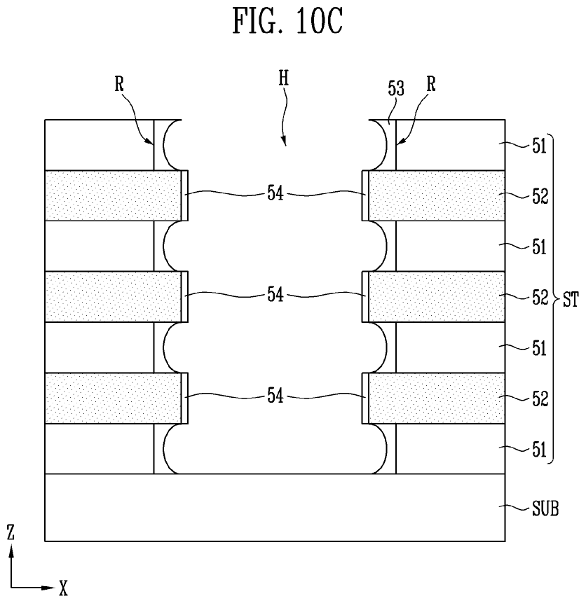

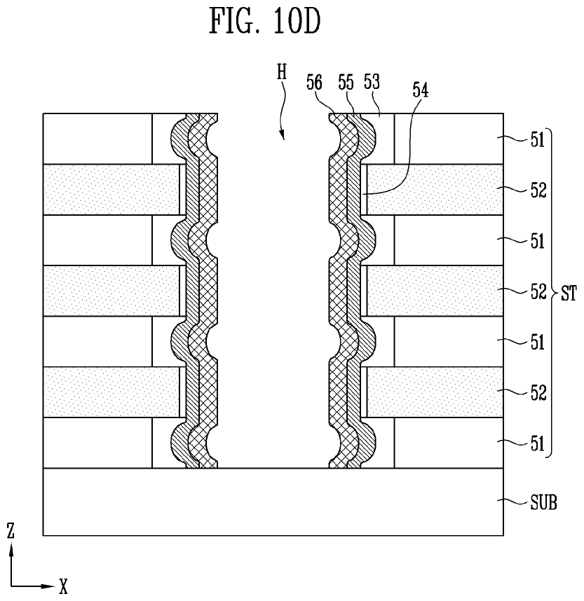

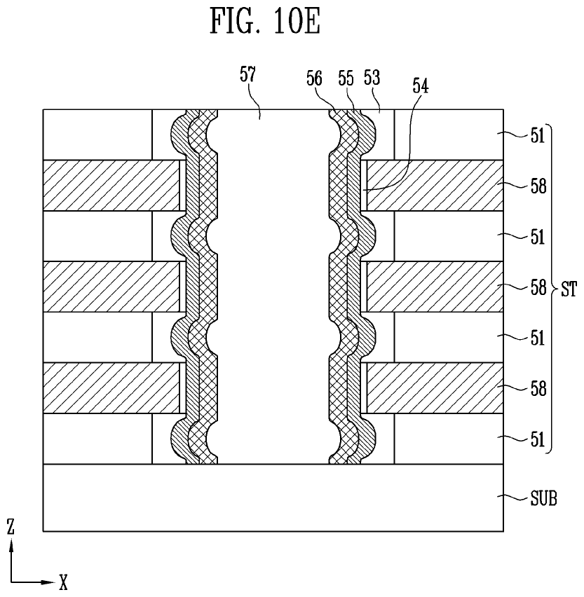

FIGS. 10A to 10E are cross-sectional views illustrating a method of manufacturing a resistive memory device according to still another embodiment of the present disclosure.

Referring to FIG. 10A, a stack structure ST is formed on a substrate SUB. The stack structure ST may include first material layers 51 and second material layers 52 that are alternately stacked. The first and second material layers 51 and 52 may extend in a first direction X, which is horizontal to the substrate SUB. The first and second material layers 51 and 52 may be stacked in a second direction Z, which is vertical to the substrate SUB. The first and second material layers 51 and 52 may be formed through a deposition process such as chemical vapor deposition (CVD).

The first material layers 51 may include a material having a high etch selectivity with respect to the second material layers 52. For example, the first material layers 51 may include an insulating material such as oxide, and the second material layers 52 may include a sacrificial material, such as nitride. As another example, the first material layers 51 may include an insulating material, such as oxide, and the second material layers 52 may include a conductive material, such as polysilicon, tungsten, molybdenum, or a metal.

Subsequently, a hole H that passes through the stack structure ST may be formed. The hole H may have a cylindrical shape extending in the second direction Z.

Referring to FIG. 10B, a sidewall of each of the first material layers 51 that is exposed through the hole H may be etched to a predetermined depth to form a recess area R. That is, the sidewall of each of the first material layers 51 may be etched to a predetermined depth so that the second material layers 52 protrude farther into the hole H compared to the first material layers 51 in the horizontal direction. The sidewall of each of the first material layers 51 may be etched to have a vertical shape. Accordingly, a sidewall of the hole H may be formed in a structure in which the rectangular-wave portions are sequentially disposed in the second direction Z, which is vertical to the substrate SUB, as shown in FIG. 10B.

Referring to FIG. 10C, a high dielectric layer 53 may be formed in a recess area R, which is a space between the vertically adjacent second material layers 52 that protrude farther into the hole H compared to the first material layers 51. For example, the high dielectric layer 53 may be formed along the sidewall of the hole H, and then an etching process may be performed to cause the high dielectric layer 53 to remain only in the recess area R, which is a space between protrusions of vertically adjacent second material layers 52. A sidewall of the high dielectric layer 53 exposed through the etching process may be concavely formed.

Thereafter, a gate insulating layer 54 may be formed on a sidewall of the exposed second material layers 52. For example, the gate insulating layer 54 may be formed by oxidizing the sidewall of the exposed second material layers 52 through a radical oxidation process.

The gate insulating layer 54 may be formed of an oxide layer. The high dielectric layer 53 may be formed of a material having a dielectric constant that is higher than that of the gate insulating layer 54.

Referring to FIG. 10D, a channel layer 55 and a variable resistance layer 56 may be sequentially formed along a sidewall of the exposed gate insulating layer 54 and the sidewall of the high dielectric layer 53.

The channel layer 55 may be formed of polysilicon. At least one of a phase variation material, a perovskite-based material, or a transition metal oxide, such as NiOx, HfOx, TaOx, TiOx, or SiHfOx, may be used for the variable resistive layer 56.

Since the channel layer 55 is formed along the concave sidewall of the high dielectric layer 53, the channel layer 55 may be formed to have a wave-like pattern in the vertical direction. For example, a partial area of the channel layer 55 may be formed concavely with respect to a center portion direction of the hole H, and an area between the concavely formed areas may be formed convexly relatively. For example, portions of the channel layer 55 that are adjacent to the first material layer 51 may be defined as a concave area, and portions that are adjacent to the second material layer 52 may be defined as a substantially straight area.

Referring to FIG. 10E, a vertical insulating layer 57 may be formed to fill an inside of the hole H of FIG. 10D. The vertical insulating layer 57 may be formed of an oxide.

Thereafter, the second material layer 52 of FIG. 10D is replaced with a third material layer 58. For example, when the second material layers 52 include a sacrificial material and the first material layers 51 include an insulating material, the second material layers 52 may be replaced with conductive layers. The third material layer 58 may include a conductive material, such as polysilicon, tungsten, molybdenum, or a metal.

As another example, when the first material layers 51 include an insulating material and the second material layers 52 include a conductive material, a process of replacing the second material layers 52 with the third material layers 58 may be skipped.

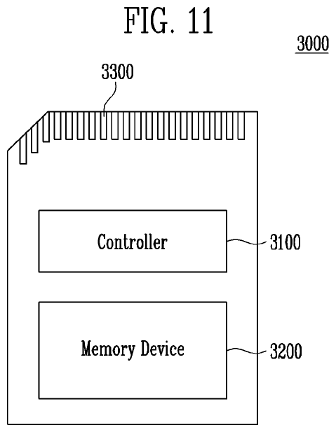

FIG. 11 is a diagram illustrating a memory card system to which a resistive memory device of the present disclosure is applied.

Referring to FIG. 11, the memory card system 3000 includes a controller 3100, a memory device 3200, and a connector 3300.

The controller 3100 may be connected to the memory device 3200. The controller 3100 may be configured to access the memory device 3200. For example, the controller 3100 may be configured to control a program, read, or erase operation of the memory device 3200 or to control a background operation. The controller 3100 may be configured to provide an interface between the memory device 3200 and a host. The controller 3100 may be configured to drive firmware for controlling the memory device 3200. For example, the controller 3100 may include components, such as a random access memory (RAM), a processing unit, a host interface, a memory interface, and an error correction circuit.

The controller 3100 may communicate with an external device through the connector 3300. The controller 3100 may communicate with an external device (for example, the host) according to a specific communication standard. For example, the controller 3100 may be configured to communicate with an external device through at least one of various communication standards such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 3300 may be defined by at least one of the various communication standards described above.

The memory device 3200 may include resistive memory cells and may be configured identically to the resistive memory device 1100 shown in FIG. 1.

The controller 3100 and the memory device 3200 may be integrated into one semiconductor device to configure a memory card. For example, the controller 3100 and the memory device 3200 may be integrated into one semiconductor device to configure a memory card, such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS).

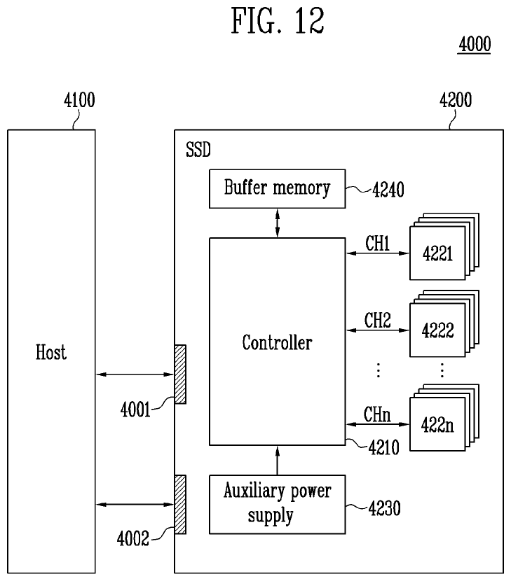

FIG. 12 is a diagram illustrating a solid state drive (SSD) system to which a resistive memory device of the present disclosure is applied.

Referring to FIG. 12, the SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to the signal that is received from the host 4100. For example, the signal may be signals based on an interface between the host 4100 and the SSD 4200. For example, the signal may be a signal that is defined by at least one of interfaces, such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The plurality of memory devices 4221 to 422n may be configured to store data and may include resistive memory cells. Each of the plurality of memory devices 4221 to 422n may be configured identically to the resistive memory device 1100, shown in FIG. 1.

The auxiliary power supply 4230 may be connected to the host 4100 through the power connector 4002. The auxiliary power supply 4230 may receive a power voltage from the host 4100 and charge the power voltage. The auxiliary power supply 4230 may provide a power voltage of the SSD 4200 when power supply from the host 4100 is not smooth. For example, the auxiliary power supply 4230 may be positioned in the SSD 4200 or may be positioned outside the SSD 4200. For example, the auxiliary power supply 4230 may be positioned on a main board and may provide auxiliary power to the SSD 4200.

The buffer memory 4240 may operate as a buffer memory of the SSD 4200. For example, the buffer memory 4240 may temporarily store data that is received from the host 4100 or data that is received from the plurality of memory devices 4221 to 422n, or may temporarily store data (for example, a mapping table) of the memory devices 4221 to 422n. The buffer memory 4240 may include a volatile memory, such as a DRAM, an SDRAM, a DDR SDRAM, and an LPDDR SDRAM, or a nonvolatile memory such as an FRAM, a ReRAM, an STT-MRAM, and a PRAM.

What is claimed is:

1. A resistive memory device comprising:
a stack structure in which a plurality of interlayer insulating layers and a plurality of conductive layers are alternately stacked;
a hole passing through the stack structure in a vertical direction;
a gate insulating layer, a channel layer, and a variable resistance layer sequentially formed along a sidewall of the hole; and
a high dielectric layer formed between the channel layer and the gate insulating layer, the high dielectric layer being adjacent to the plurality of interlayer insulating layers.

2. The resistive memory device of claim 1, wherein the high dielectric layer has a higher dielectric constant that is higher than the gate insulating layer.

3. The resistive memory device of claim 1, wherein the plurality of conductive layers protrude farther into the hole compared to the plurality of interlayer insulating layers, and
wherein the high dielectric layer is disposed only in a space between the plurality of protruding conductive layers.

4. The resistive memory device of claim 3, wherein the high dielectric layer is disposed only in the space between vertically adjacent conductive layers, among the plurality of conductive layers, and
wherein the high dielectric layer that is disposed in the space between the plurality of protruding conductive layers has a concave sidewall that is in contact with the channel layer.

5. The resistive memory device of claim 1, wherein the channel layer has a wave-like pattern extending in the vertical direction.

6. The resistive memory device of claim 5, wherein the channel layer includes a concave area that is adjacent to the plurality of interlayer insulating layers and a substantially straight area that is adjacent to the plurality of conductive layers.

7. A resistive memory device comprising:
a stack structure in which a plurality of interlayer insulating layers and a plurality of conductive layers are alternately stacked;
a hole passing through the stack structure in a vertical direction;
a channel layer and a variable resistance layer sequentially formed along a sidewall of the hole;
a gate insulating layer disposed between the plurality of conductive layers and the channel layer; and
a high dielectric layer disposed between the plurality of interlayer insulating layers and the channel layer.

8. The resistive memory device of claim 7, wherein the high dielectric layer has a higher dielectric constant that is higher than the gate insulating layer.

9. The resistive memory device of claim 7, wherein the plurality of conductive layers protrude farther into the hole compared to the plurality of interlayer insulating layers, and
wherein the high dielectric layer is disposed only in a space between the plurality of protruding conductive layers.

10. The resistive memory device of claim 9, wherein the high dielectric layer is disposed only in the space between vertically adjacent conductive layers, among the plurality of conductive layers, and
wherein the high dielectric layer that is disposed in the space between the plurality of protruding conductive layers has a concave sidewall that is in contact with the channel layer.

11. The resistive memory device of claim 7, wherein the channel layer has a wave-like pattern extending in the vertical direction.

12. The resistive memory device of claim 11, wherein the channel layer includes a concave area that is adjacent to the plurality of interlayer insulating layers and a substantially straight area that is adjacent to the plurality of conductive layers.

13. A resistive memory device comprising:
a stack structure in which a plurality of interlayer insulating layers and a plurality of conductive layers are alternately stacked;
a hole passing through the stack structure in a vertical direction;
a gate insulating layer, a channel layer, and a variable resistance layer sequentially formed along a sidewall of the hole; and
a high dielectric layer formed between a sidewall of the plurality of interlayer insulating layers and the gate insulating layer.

14. The resistive memory device of claim 13, wherein the high dielectric layer has a higher dielectric constant that is higher than that of the gate insulating layer.

15. The resistive memory device of claim 13, wherein the plurality of conductive layers protrude farther into the hole compared to the plurality of interlayer insulating layers, and
wherein the high dielectric layer is disposed only in a space between the plurality of protruding conductive layers.

16. The resistive memory device of claim 15, wherein the high dielectric layer is disposed only in the space between vertically adjacent conductive layers, among the plurality of conductive layers, and
wherein the high dielectric layer that is disposed in the space between the plurality of protruding conductive layers has a concave sidewall that is in contact with the channel layer.

17. The resistive memory device of claim 13, wherein the channel layer has a wave-like pattern extending in the vertical direction.

18. The resistive memory device of claim 17, wherein the channel layer includes a concave area that is adjacent to the plurality of interlayer insulating layers and a substantially straight area that is adjacent to the plurality of conductive layers.

19. A method of manufacturing a resistive memory device, the method comprising:
forming a hole passing through a stack structure in which a plurality of first material layers and a plurality of second material layers are alternately stacked in a vertical direction;
forming recess areas by etching sidewalls of the plurality of first material layers, exposed through the hole, to a predetermined depth;
forming a gate insulating layer along a sidewall of the hole including the recess areas and forming a high dielectric layer on the gate insulating layer in the recess areas; and
forming a channel layer and a variable resistance layer along a sidewall of the gate insulating layer and a sidewall of the high dielectric layer.

20. The method of claim 19, wherein the high dielectric layer has a higher dielectric constant than the gate insulating layer.

21. The method of claim 19, wherein forming the gate insulating layer comprises:
forming a sacrificial layer along a sidewall of the hole including the recess area; and
forming the gate insulating layer by oxidizing the sacrificial layer.

22. The method of claim 19, wherein forming the high dielectric layer comprises:
forming the high dielectric layer on a surface of the gate insulating layer to fill the recess area; and
performing an etching process so that the gate insulating layer that is formed on sidewalls of the plurality of second material layer is exposed and the high dielectric layer remains only in the recess area.

23. The method of claim 22, wherein the etching process is performed so that the sidewall of the high dielectric layer is concave.

24. The method of claim 22, wherein forming the channel layer and the variable resistance layer comprises sequentially forming the channel layer and the variable resistance layer along the sidewall of the concave high dielectric layer and the sidewall of the gate insulating layer, and
wherein the channel layer is formed in a wave-like pattern extending in the vertical direction.

25. A method of manufacturing a resistive memory device, the method comprising:
forming a hole passing through a stack structure in which a plurality of first material layers and a plurality of second material layers are alternately stacked in a vertical direction;
forming recess areas by etching sidewalls of the plurality of first material layers, exposed through the hole, to a predetermined depth;
forming a first sacrificial layer along a sidewall of the hole including the recess areas and forming a second sacrificial layer on the first sacrificial layer in the recess areas;
forming a gate insulating layer by oxidizing a portion of the first sacrificial layer, the portion of the first sacrificial layer that is formed on sidewalls of the plurality of second material layers;
removing the remaining first sacrificial layer and second sacrificial layer and forming a high dielectric layer in recess areas from which the first sacrificial layer and the second sacrificial layer are removed; and
forming a channel layer and a variable resistance layer along a sidewall of the gate insulating layer and a sidewall of the high dielectric layer.

26. The method of claim 25, wherein the high dielectric layer has a higher dielectric constant than the gate insulating layer.

27. The method of claim 25, wherein the first sacrificial layer is a polysilicon layer, and
wherein the second sacrificial layer is a nitride layer.

28. The method of claim 25, forming the high dielectric layer comprises:
forming the high dielectric layer to fill the recess area; and
performing an etching process so that the gate insulating layer that is formed on the sidewalls of the plurality of second material layers is exposed and the high dielectric layer remains only in the recess area.

29. The method of claim 28, wherein the etching process is performed so that the sidewall of the high dielectric layer is concave.

30. The method of claim 29, wherein forming the channel layer and the variable resistance layer comprises sequentially forming the channel layer and the variable resistance layer along the sidewall of the concave high dielectric layer and the sidewall of the gate insulating layer, and
wherein the channel layer is formed in a wave-like pattern extending in the vertical direction.

31. A method of manufacturing a resistive memory device, the method comprising:
forming a hole passing through a stack structure in which a plurality of first material layers and a plurality of second material layers are alternately stacked in a vertical direction;
forming recess areas by etching sidewalls of the plurality of first material layers, exposed through the hole, to a predetermined depth;
forming a high dielectric layer in the recess areas; and
forming a gate insulating layer, a channel layer, and a variable resistance layer along sidewalls of the plurality of second material layers and a sidewall of the high dielectric layer.

32. The method of claim 31, wherein the high dielectric layer has a higher dielectric constant than the gate insulating layer.

33. The method of claim 31, wherein forming the high dielectric layer comprises etching so that the sidewall of the high dielectric layer is concave.

34. The method of claim 33, wherein forming the gate insulating layer, the channel layer, and the variable resistance layer comprises sequentially forming the gate insulating layer, the channel layer, and the variable resistance layer along the sidewall of the concave high dielectric layer and the sidewalls of the plurality of second material layers, and
wherein the channel layer is formed in a wave-like pattern extending in the vertical direction.

35. A method of manufacturing a resistive memory device, the method comprising:
forming a hole passing through a stack structure in which a plurality of first material layers and a plurality of second material layers are alternately stacked in a vertical direction;
forming recess areas by etching sidewalls of the plurality of first material layers, exposed through the hole, to a predetermined depth;
forming a high dielectric layer in the recess areas;
forming a gate insulating layer on a sidewall of the plurality of second material layers; and
forming a gate insulating layer, a channel layer, and a variable resistance layer along a sidewall of the gate insulating layer and a sidewall of the high dielectric layer.

36. The method of claim 35, wherein the high dielectric layer has a dielectric constant than the gate insulating layer.

37. The method of claim 35, wherein forming the gate insulating layer comprises forming the gate insulating layer by oxidizing the sidewalls of the plurality of second material layers that are exposed through the hole.

38. The method of claim 35, wherein forming the high dielectric layer comprises etching so that the sidewall of the high dielectric layer is concave.

39. The method of claim 38, wherein forming the channel layer and the variable resistance layer comprises sequentially forming the channel layer and the variable resistance layer along the sidewall of the gate insulating layer and the sidewall of the concave high dielectric layer, and
wherein the channel layer is formed in a wave-like pattern extending in the vertical direction.
